(19) United States
(12) Patent Application Publication
(10) Pub. No.: US 2024/0203701 A1
(43) Pub. Date: Jun. 20, 2024

(54) SUBSTRATE PROCESSING APPARATUS AND SUBSTRATE PROCESSING METHOD

(71) Applicant: SAMSUNG ELECTRONICS CO., LTD., Suwon-si (KR)

(72) Inventors: Soonku Kwon, Suwon-si (KR); Sunggil Kang, Suwon-si (KR); Chanyeong Jeong, Suwon-si (KR); Jeongmin Bang, Suwon-si (KR); Yeongkwang Lee, Suwon-si (KR); Ilgon Choi, Suwon-si (KR)

(73) Assignee: SAMSUNG ELECTRONICS CO., LTD., Suwon-si (KR)

(21) Appl. No.: 18/523,234

(22) Filed: Nov. 29, 2023

(30) Foreign Application Priority Data
Dec. 19, 2022 (KR) 10-2022-0178694

(51) Int. Cl. H01J 37/32

(52) U.S. Cl. CPC H01J 37/32522; H01J 37/32422; H01J 2237/002

(57) ABSTRACT

A substrate processing apparatus includes a chamber including a first space and a second space, a substrate support in the first space and configured to support a substrate, a plasma source configured to generate plasma in the second space, an ion blocker between the second space and the first space, the ion blocker including through-holes configured to pass therethrough radicals of the plasma from the second space to the first space and provide the radicals to the substrate, and a temperature controller including a plurality of heaters connected to the ion blocker, one or more chillers, and a controller configured to control output of the plurality of heaters and output of the one or more chillers, where the ion blocker includes a plurality of regions, each of the plurality of regions including a heating line, one or more boundary regions.

### CROSS-REFERENCE TO RELATED APPLICATION

This application is based on and claims priority to Korean Patent Application No. 10-2022-0178694, filed on Dec. 19, 2022, in the Korean Intellectual Property Office, the disclosure of which is incorporated by reference herein in its entirety.

### BACKGROUND

### 1. Field

The disclosure relates to a substrate processing apparatus and a substrate processing method, and more particularly, to a substrate processing apparatus and a substrate processing method for controlling a radical dispersion.

### 2. Description of Related Art

Wet cleaning processes have a limit in fine processes at the level of several nanometers due to the surface tension of liquids. To overcome such a limit, dry cleaning processes using radicals with high reactivity have been used recently.

Dry etching process equipment uses methods in which plasma is generated in electrically separated spaces above processing spaces rather than in the processing spaces. The methods may include selectively supplying only radicals having no polarity to the processing spaces by using ion blockers, thereby reacting the radicals with wafers.

To increase the number of chips that may be produced by performing a process once, the sizes of wafers may be increased. Therefore, dispersion control may be utilized for uniformly processing entire areas of wafers. In dry cleaning processes, density distributions of radicals supplied to processing spaces affect wafer dispersions. Radical density distributions are determined by plasma density dispersions and gas flow.

Information disclosed in this Background section has already been known to or derived by the inventors before or during the process of achieving the embodiments of the present application, or is technical information acquired in the process of achieving the embodiments. Therefore, it may contain information that does not form the prior art that is already known to the public.

### SUMMARY

One or more example embodiments provide a substrate processing apparatus including an ion blocker, which may be divided into a plurality of regions and may allow respective temperatures of the plurality of regions to be independently controlled.

One or more example embodiments provide a substrate processing method using an ion blocker, which may be divided into a plurality of regions and may allow respective temperatures of the plurality of regions to be independently controlled.

Additional aspects will be set forth in part in the description which follows and, in part, will be apparent from the description, or may be learned by practice of the presented embodiments.

According to an aspect of an example embodiment, a substrate processing apparatus may include a chamber including a first space and a second space, a substrate support in the first space and configured to support a substrate, a plasma source configured to generate plasma in the second space, an ion blocker between the second space and the first space, the ion blocker including through-holes configured to pass therethrough radicals of the plasma from the second space to the first space and provide the radicals to the substrate, and a temperature controller including a plurality of heaters connected to the ion blocker, one or more chillers, and a controller configured to control output of the plurality of heaters and output of the one or more chillers, where the ion blocker may include a plurality of regions, each of the plurality of regions including a heating line, one or more boundary regions each including a cooling flow path between at least two of the plurality of regions and respectively connected to the one or more chillers, where a temperature of each of the plurality of regions may be independently controlled, and where the heating lines of the plurality of regions may be respectively connected to the plurality of heaters.

According to an aspect of an example embodiment, a substrate processing apparatus may include a chamber including a first space and a second space, a plasma source configured to generate plasma in the second space, a substrate support in the first space and configured to support a substrate, and an ion blocker between the second space and the first space, the ion blocker including through-holes configured to pass therethrough radicals of the plasma from the second space to the first space and provide the radicals to the substrate, where the ion blocker may include a first region including a first heating line connected to a first heater, a second region including a second heating line connected to a second heater, and a first boundary region between the first region and the second region, the first boundary region including a first cooling flow path connected to a first chiller, and where a first temperature of the first region may be controlled independently of a second temperature of the second region.

According to an aspect of an example embodiment, a substrate processing method may include loading a substrate into a chamber, generating plasma in the chamber, controlling a temperature of an ion blocker in the chamber, and processing the substrate using radicals of the plasma, the radicals having passed through the ion blocker, where the ion blocker may include a plurality of regions each including a heating line connected to a heater, and one or more boundary regions between at least two of the plurality of regions, each of the one or more boundary regions including a cooling flow path connected to a chiller, and where the controlling of the temperature of the ion blocker may include independently controlling temperatures of each of the plurality of regions and temperatures of the one or more boundary regions.

### BRIEF DESCRIPTION OF DRAWINGS

The above and other aspects, features, and advantages of certain example embodiments of the present disclosure will be more apparent from the following description taken in conjunction with the accompanying drawings, in which:

FIG. 1 is a diagram illustrating a substrate processing apparatus according to an embodiment;

FIG. 2 is a diagram illustrating an upper surface of an ion blocker according to an embodiment;

FIG. 3 is a diagram illustrating a lateral surface of an ion blocker according to an embodiment;

FIG. 4 is a graph illustrating changes in a recombination coefficient of fluorine in accordance with changes in a surface temperature of an ion blocker according to an embodiment;

FIG. 5 is a diagram illustrating a reaction mechanism in a through-hole of an ion blocker according to an embodiment;

FIG. 6 is a diagram illustrating a temperature change in a region and a boundary region of an ion blocker according to an embodiment;

FIG. 7 is a diagram illustrating a lateral surface of an ion blocker according to a comparative example;

FIG. 8 is a diagram illustrating a temperature change in a region and a boundary region of an ion blocker according to a comparative example;

FIG. 9 is a diagram illustrating a substrate processing apparatus according to an embodiment;

FIG. 10 is a diagram illustrating a substrate processing apparatus according to an embodiment; and

FIG. 11 is a diagram illustrating a substrate processing apparatus according to an embodiment.

### DETAILED DESCRIPTION OF EMBODIMENTS

Hereinafter, example embodiments of the disclosure will be described in detail with reference to the accompanying drawings. The same reference numerals are used for the same components in the drawings, and redundant descriptions thereof will be omitted. The embodiments described herein are example embodiments, and thus, the disclosure is not limited thereto and may be realized in various other forms.

As used herein, expressions such as “at least one of,” when preceding a list of elements, modify the entire list of elements and do not modify the individual elements of the list. For example, the expression, “at least one of a, b, and c,” should be understood as including only a, only b, only c, both a and b, both a and c, both b and c, or all of a, b, and c.

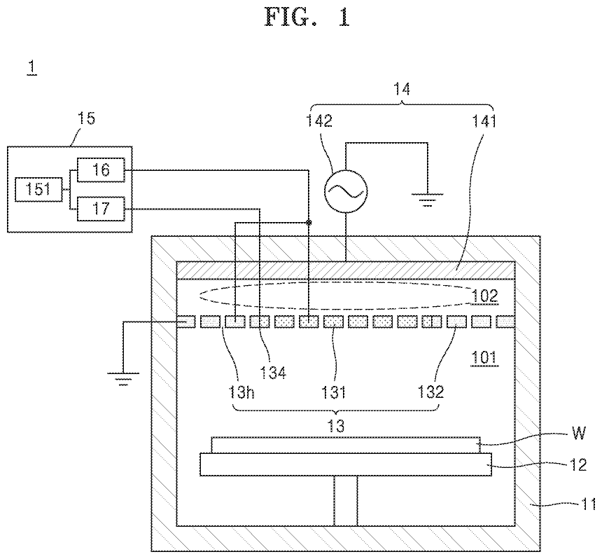

FIG. 1 is a diagram illustrating a substrate processing apparatus according to an embodiment. FIG. 1 shows a chamber 11 in a cross-sectional view.

Referring to FIG. 1, a substrate processing apparatus 1 may include a chamber 11, a substrate support 12, an ion blocker 13, a plasma source 14, and a temperature controller 15.

The chamber 11 may include a first space 101 and a second space 102. The first space 101 may be a processing space for processing a substrate W. The second space 102 may be a space in which plasma is generated by the plasma source 14.

The chamber 11 may have a cylindrical shape. The chamber 11 may include a metal. For example, the material of the chamber 11 may include aluminum (Al). The chamber 11 may be grounded. An opening may be formed in one sidewall of the chamber 11 and may be used as a gate through which the substrate W may be loaded and unloaded.

An exhaust pipe for discharging by-products generated during a process may be connected to a lower wall of the chamber 11. A pump for maintaining a process pressure in the chamber 11 during a process, a valve for opening and shutting a passage in the exhaust pipe, and the like may be mounted on the exhaust pipe.

The substrate support 12 may be arranged in the chamber 11. The substrate support 12 may be arranged in a lower portion of the first space 101 and support the substrate W. The substrate support 12 may include an electrostatic chuck securing the substrate W with electrostatic force, but the substrate support 12 of the disclosure is not limited to the electrostatic chuck. The substrate support 12 may have a substantially circular plate shape. The substrate support 12 may secure the substrate W by, for example, an electrostatic force, mechanical clamping, and/or other methods as will be understood by one of ordinary skill in the art from the disclosure herein.

A heating member may be mounted inside the substrate support 12 and may be configured to heat the substrate W. Heat generated by the heating member may be transferred to the substrate W, and the substrate W may be maintained at a temperature required for a process, by the transferred heat.

A cooling flow path may be formed inside the substrate support 12 and may be configured to cool the substrate W. A cooling fluid may be provided to the cooling flow path. The cooling fluid may maintain the substrate W at a temperature, which is required for a process, by cooling the substrate W while flowing along the cooling flow path.

The plasma source 14 may generate plasma from a process gas supplied to the second space 102. FIG. 1 illustrates that a capacitive coupled plasma (CCP) source is used as the plasma source 14, but the disclosure is not limited thereto. For example, methods, such as a remote plasma source (RPS), inductively coupled plasma (ICP), and microwaves, may be used.

The plasma source 14 may include an upper electrode 141, a lower electrode, and a power supply 142. FIG. 1 illustrates that the upper electrode 141 is attached to an upper portion of the chamber 11, but the upper electrode 141 may be arranged in an upper inner space of the chamber 11 (e.g., second space 102). The lower electrode may be provided to an inner space of the substrate support 12. The power supply 142 may apply RF power or microwave power to the upper electrode 141 or the lower electrode. Power may be selectively applied to one of the upper electrode 141 and the lower electrode, and the other may be grounded. For example, power may be applied to the upper electrode 141, and the lower electrode may be grounded.

The ion blocker 13 may separate the first space 101 and the second space 102 as upper and lower sides, respectively. The process gas may be provided to the second space 102 by a gas supply unit. An electromagnetic field generated between the upper electrode 141 and the ion blocker 13 may excite the process gas into a plasma state. The process gas excited into the plasma state (hereinafter, referred to as a plasma effluent) may include radicals, ions, and/or electrons.

The ion blocker 13 may be formed of a conductive material and may have, for example, a plate shape, such as a circular plate. A constant voltage (for example, a ground voltage) may be connected to the ion blocker 13, but the disclosure is not limited thereto. The ion blocker 13 may include a plurality of through-holes 13h that are formed in a vertical direction.

Radicals or uncharged neutral species out of the plasma effluent may pass through the through-holes 13h of the ion blocker 13. On the other hand, it may be difficult for charged species (that is, ions) to pass through the through-holes 13h. For example, when the process gas, which generates plasma, includes nitrogen trifluoride (NF3), fluorine-containing radicals (F*, NF3*, and the like) may pass through the ion blocker 13.

The ion blocker 13 of the substrate processing apparatus 1 according to an embodiment may include a plurality of regions, such as region 131 and region 132. The ion blocker 13 may be connected to the temperature controller 15. The temperature controller 15 may include a heater 16, a chiller 17, and a controller 151 configured to control the heater 16 and the chiller 17. The controller 151 may be configured to perform temperature control on each region of the ion blocker 13 and may include a processor and a memory device. Each of the plurality of regions 131 and 132 of the ion blocker 13 may include a heating line. The heating lines may be respectively connected to heaters of the heater 16, and thus, a temperature of each of the plurality of regions 131 and 132 may be independently controlled. The heating line may include, for example, an electrical resistance-type heating element.

The plurality of regions 131 and 132 may include a first region 131 and a second region 132. The first region 131 may be located on a further inside of the ion blocker 13 than the second region 132. For example, the second region 132 may surround at least a portion of the first region 131. The first region 131 may be a central region of the ion blocker 13, which vertically overlaps or at least partially vertically overlaps a central region of the substrate W, and the second region 132 may be an edge region of the ion blocker 13, which vertically overlaps or at least partially vertically overlaps an edge region of the substrate W. The first region 131 and the second region 132 may form a concentric circle. Although FIG. 1 illustrates that the ion blocker 13 includes the first region 131 and the second region 132, the number of regions in the ion blocker 13 may increase, as needed. In other words, the ion blocker 13 may include three or more regions that may be independently controlled in terms of temperature.

A boundary region (e.g., region 134) may be arranged between the plurality of regions 131 and 132. The boundary region 134 may include a cooling flow path connected to the chiller 17. The number of boundary regions may be one and may increase with the increasing number of regions in the ion blocker 13. As the cooling flow path, through which a cooling fluid flows, is provided to the boundary region 134 between the plurality of regions 131 and 132, thermal separation between the plurality of regions 131 and 132 may be enhanced.

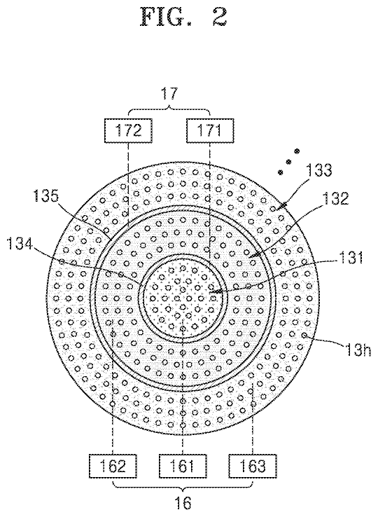

FIG. 2 is a diagram illustrating an upper surface of an ion blocker according to an embodiment.

Referring to FIG. 2, the ion blocker 13 of the substrate processing apparatus 1 of the disclosure may include the first region 131, the second region 132, a third region 133, a first boundary region 134, and a second boundary region 135.

The first region 131 may be connected to a first heater 161 of the heater 16. The second region 132 may be connected to a second heater 162 of the heater 16. The third region 133 may be connected to a third heater 163 of the heater 16. The first region 131, the second region 132, and the third region 133 are independently connected to the first, second, and third heaters 161, 162, and 163, respectively, whereby a temperature of each of the first region 131, the second region 132, and the third region 133 may be independently controlled.

The first heater 161, the second heater 162, and the third heater 163 may be respectively connected to heating lines inside the first, second, and third regions 131, 132, and 133. By independently controlling outputs of the first heater 161, the second heater 162, and the third heater 163, temperatures of a plurality of regions (that is, 131, 132, and 133) may be independently controlled.

The first boundary region 134 may be connected to a first chiller 171 of the chiller 17. The second boundary region 135 may be connected to a second chiller 172 of the chiller 17. The first chiller 171 and the second chiller 172 may be respectively connected to cooling flow paths inside the first and second boundary regions 134 and 135. Each of the first chiller 171 and the second chiller 172 may include a cooling fluid supplier for supplying a cooling fluid to a cooling flow path of the ion blocker 13. By independently controlling outputs (for example, a temperature of the cooling fluid and/or a flow rate of the cooling fluid) of the first chiller 171 and the second chiller 172, temperatures of the boundary regions (that is, 134 and 135) and the plurality of regions (that is, 131, 132, and 133) may be adjusted.

The first region 131, the second region 132, and the third region 133 of the ion blocker 13 may be electrically connected to each other. The first region 131, the second region 132, and the third region 133 may be electrically grounded.

The diameter of each of the through-holes 13h of the ion blocker 13 may be smaller than twice the thickness of a plasma sheath. For example, the diameter of each of the through-holes 13h may be equal to or smaller than about 1 mm.

The plasma sheath refers to a region in which positive charges and neutrons are present in a relatively larger amount between plasma and a surface, such as a wall surface, than electrons. The plasma sheath may be generated due to a difference in moving speeds between electrons and ions in the plasma.

Because the ion blocker 13 is electrically grounded, the diameter of each of the through-holes 13h may be determined by considering the plasma sheath, such that electrons or ions do not pass through the through-holes 13h. The plasma sheath may be formed on inner circumferential surfaces of the through-holes 13h. When the diameter of each of the through-holes 13h is smaller than twice the thickness of the plasma sheath, a plasma bulk is unable to be formed in the through-holes 13h due to the plasma sheath. Because the plasma bulk is not formed in the through-holes 13h, electrons or ions are unable to pass through the through-holes 13h.

In dry cleaning processes, a density distribution of radicals supplied to the processing space (for example, the first space 101) affects a substrate W dispersion. The radical density distribution may be determined by a plasma density dispersion and process gas flow. According to a comparison example, to improve a dispersion of a plasma density, a separate shower head may be mounted under an ion blocker. In addition, methods, such as changing the size of a through-hole of the shower head or changing an interval between through-holes of the shower head, may be used. However, such methods have an issue of inconvenience because changes in hardware (shower head mounting, the type of shower head, and the like) are required for process dispersion optimization.

The substrate processing apparatus 1 of the disclosure may use the ion blocker 13 that is divided into (i.e., that includes) the plurality of regions (that is, 131, 132, and 133), whereby the temperatures of the plurality of regions (that is, 131, 132, and 133) may be independently controlled. Therefore, even without changes in hardware, the radical density in the first space 101 may be controlled, and the substrate W dispersion may be optimized.

The substrate processing apparatus 1 of the disclosure may further include one or more temperature sensors, which may respectively detect the temperatures of the plurality of regions (that is, 131, 132, and 133) of the ion blocker 13. The temperature sensors may be contact-type temperature sensors mounted inside the ion blocker 13. In addition, the temperature sensors may be non-contact-type temperature sensors mounted apart from the ion blocker 13 by as much as a certain interval.

The temperature controller 15 may control the heat unit 16 and the chiller 17 through feedback of the temperatures of the plurality of regions (that is, 131, 132, and 133), which are measured by the temperature sensors. Due to the feedback of the temperatures measured by the temperature sensors, the controller 151 of the temperature controller 15 may adjust the respective outputs of the first, second, and third heaters 161, 162, and 163 and the respective outputs of the first and second chillers 171 and 172.

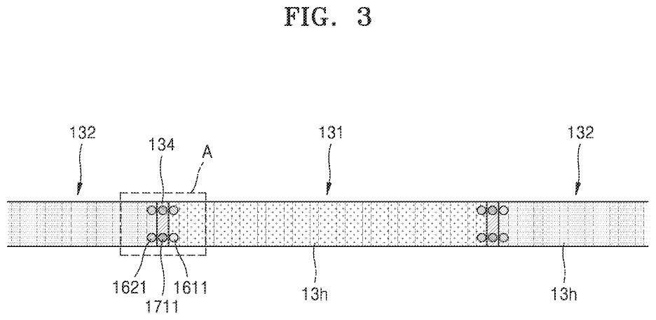

FIG. 3 is a diagram illustrating a lateral surface of an ion blocker according to an embodiment.

Referring to FIG. 3, a first heating line 1611 may be arranged in the first region 131 of the ion blocker 13, and a second heating line 1621 may be arranged in the second region 131 of the ion blocker 13. The first heating line 1611 may be arranged in an outer portion of the first region 131 to be adjacent to the second region 132. The second heating line 1621 may be arranged in an inner portion of the second region 132 to be adjacent to the first region 131.

The first heating line 1611 may be connected to the first heater 161. The second heating line 1621 may be connected to the second heater 162. The first heating line 1611 and the second heating line 1621 may form a concentric circle. In addition, FIG. 3 illustrates that each of the first heating line 1611 and the second heating line 1621 has a 2-stage structure, but the disclosure is not limited thereto.

The first boundary region 134 may be arranged between the first region 131 and the second region 132. A first cooling flow path 1711 may be arranged in the first boundary region 134. The first cooling flow path 1711 is a flow path provided to the ion blocker 13 for a cooling fluid supplied from the chiller 17 to flow and may include at least one inlet for inflow of the cooling fluid supplied from the chiller 17 and at least one outlet for outflow of the cooling fluid returning to the chiller 17.

By mounting the first cooling flow path 1711 in the first boundary region 134, the temperature of a zone (region A), in which the first region 131 and the second region 132 are adjacent to each other, may be adjusted. That is, even in the zone (region A) in which the first region 131 and the second region 132 are adjacent to each other, the temperatures of the first region 131 and the second region 132 may be independently adjusted.

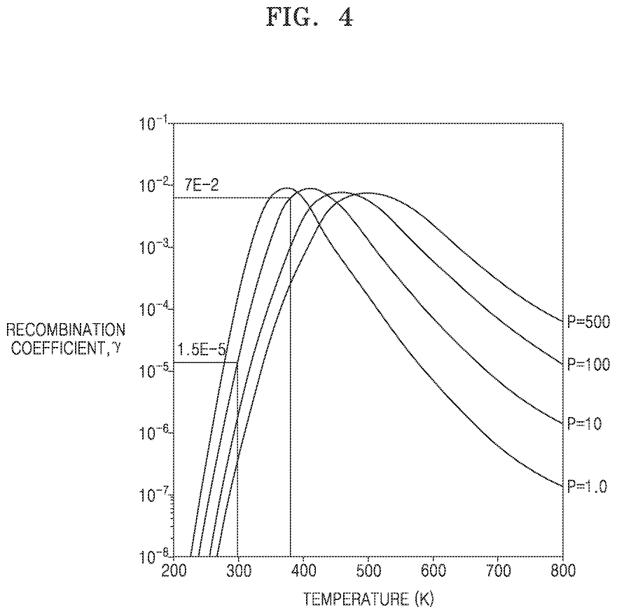

FIG. 4 is a graph illustrating changes in a recombination coefficient of fluorine in accordance with changes in a surface temperature of an ion blocker according to an embodiment.

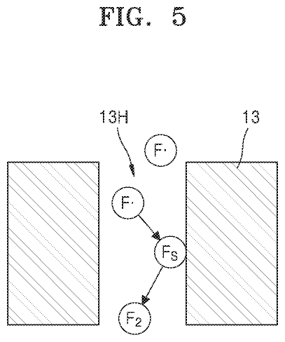

FIG. 5 is a diagram illustrating a reaction mechanism in a through-hole of an ion blocker according to an embodiment.

The ion blocker 13 may include a metal material. In addition, the ion blocker 13 may include an etch-resistant material layer extending along the inner circumferential surfaces of the through-holes 13h. For example, the ion blocker 13 may include an aluminum (Al) material, and the etch-resistant material layer extending along the inner circumferential surfaces of the through-holes 13h may include nickel (Ni).

Referring to FIG. 4, the recombination coefficient of fluorine may vary with temperatures. Radicals react with and thus are recombined with a metal surface, and there may be a change in the recombination coefficient depending on temperatures of the metal surface.

For example, in the case of a reaction between fluorine and a nickel surface, the recombination coefficient may sharply increase with increasing temperatures at 100° C. or less and decrease at 100° C. or more. Comparing the recombination coefficients at 27° C. and 100° C., there is a difference of about 5000 times therebetween. Thus, the temperatures of the plurality of regions of the ion blocker 13 may be independently controlled, whereby the substrate processing apparatus 1 of the disclosure may adjust proportions of F· and F2 (See FIG. 5) for each region. As a result, the substrate W dispersion may be adjusted due to a difference in reactivity between an etchant material and F· and/or F2.

By independently controlling the temperatures of the plurality of regions, the substrate processing apparatus 1 of the disclosure may adjust recombination coefficients of radicals passing through the through-holes 13h of each region. The process dispersion of the substrate W may be adjusted by adjusting the recombination coefficients of the radicals passing through the through-holes 13h. Therefore, even without changes in hardware, the radical density in the first space 101 may be controlled, and the substrate W dispersion may be optimized.

Referring to FIG. 5, fluorine may collide with and react with the inner circumferential surfaces of the through-holes 13h of the ion blocker 13. Fluorine having high reactivity collides with the inner circumferential surfaces of the through-holes 13h of nickel materials, and thus, fluorine may be adsorbed onto the inner circumferential surfaces of the through-holes 13h. Fluorine may be covalently bonded to the inner circumferential surfaces of the through-holes 13h. A process of the adsorption of fluorine is as represented by Equation (1).

$$F \cdot \to {F}_{S} \qquad ( 1 )$$

New radicals react with fluorine adsorbed onto the inner circumferential surfaces of the through-holes 13h, thereby performing recombination. Fluorine adsorbed onto the inner circumferential surfaces of the through-holes 13h may perform recombination and thus be desorbed from the inner circumferential surfaces of the through-holes 13h. A process of the recombination of fluorine is as represented by Equation (2).

$$F \cdot + {F}_{S} \to {F}_{2} \qquad ( 2 )$$

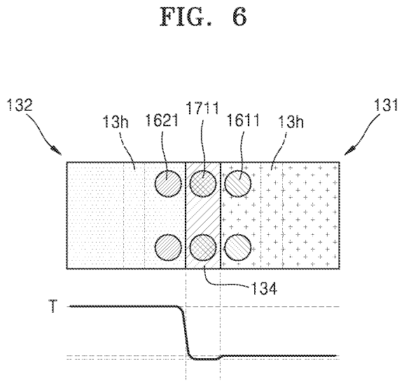

FIG. 6 is a diagram illustrating a temperature change in a region and a boundary region of an ion blocker according to an embodiment.

Referring to FIG. 6, the first boundary region 134 may be arranged between the first region 131 and the second region 132. The first heating line 1611 may be arranged in the first region 131, and the second heating line 1621 may be arranged in the second region 131. The first cooling flow path 1711 may be arranged in the first boundary region 134.

The first region 131 and the second region 131 may be controlled to have different temperatures. For example, the first region 131 and the second region 131 may output different temperatures. The temperature of the first boundary region 134 may be controlled to be equal to or smaller than the temperature of a lower-temperature region out of the first region 131 and the second region 132. FIG. 6 illustrates that the temperature of the first boundary region 134 is controlled to be equal to or smaller than the temperature of the first region 131, but the disclosure is not limited thereto.

By mounting the first cooling flow path 1711 in the first boundary region 134, a temperature influence between the first region 131 and the second region 132 may be minimized. By mounting the first cooling flow path 1711 between the first heating line 1611 and the second heating line 1621, heat or cold from the temperature of a region having a lower temperature may be prevented from flowing to a region having a higher temperature (i.e., the temperature of the region having the lower temperature that may affect the temperature of the region having the higher temperature may be minimized or prevented, such that the temperature of the lower temperature region does not affect the temperature level of the temperature of the higher temperature region).

For example, when the temperature of the first boundary region 134 is controlled to be equal to or smaller than the temperature of the first region 131, the heat or cold of the first region 131 does not flow to the second region 132. Therefore, because there is a change in temperature only at boundary surfaces of first region 131 and/or the second region 132, the temperatures of the plurality of regions may be independently controlled.

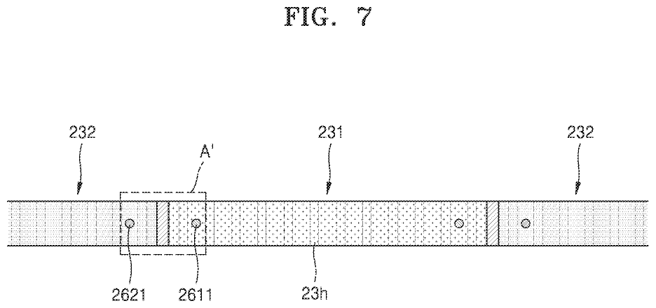

FIG. 7 is a diagram illustrating a lateral surface of an ion blocker according to a comparative example.

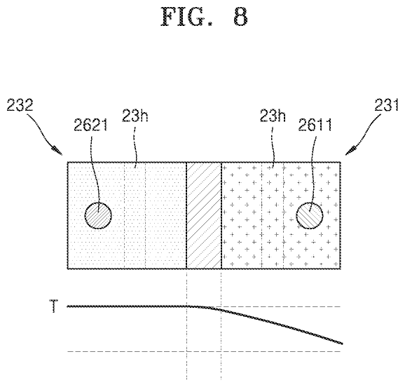

FIG. 8 is a diagram illustrating a temperature change in a region and a boundary region of the ion blocker according to the comparative example.

Referring to FIGS. 7 and 8, the ion blocker according to the comparison example may include a first region 231 and a second region 232. The first region 231 and the second region 232 may respectively include a first heating line 2611 and a second heating line 2621. The ion blocker according to the comparison example does not include a cooling flow path, as compared with the disclosure.

When temperatures are controlled by using only the first and second heating lines 2611 and 2621 as in the comparison example, there may be a zone, in which a temperature slowly changes along with positions, in a region having a lower temperature. For example, the temperature of the first region 231 may slowly decrease with an increasing distance from the second region 232. When there is a large difference in heat capacity between a plurality of regions (that is, 231 and 232), the temperature of a region having a lower temperature flows to a region having a higher temperature, and the ion blocker may unable to perform independent temperature control for each region.

In addition, because all the regions (that is, 231 and 232) of the ion blocker need to be electrically connected to each other and be electrically grounded, there is an issue in that it is difficult to insert an insulator between the plurality of regions (that is, 231 and 232) to minimize heat transfer therebetween.

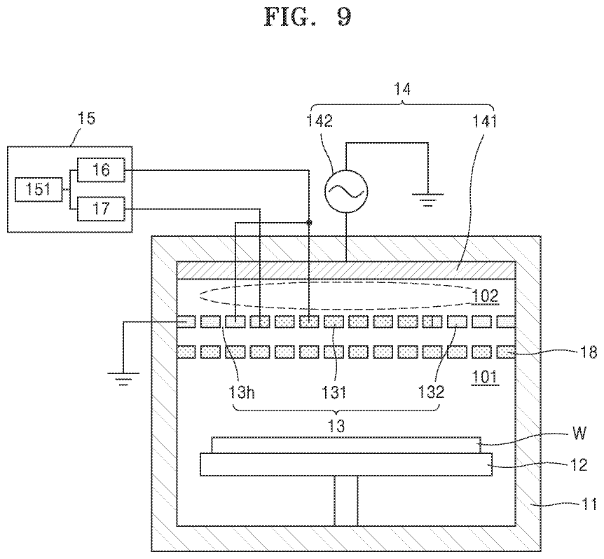

FIG. 9 is a diagram illustrating a substrate processing apparatus according to an embodiment. FIG. 9 shows a chamber 11 in a cross-sectional view.

Referring to FIG. 9, the substrate processing apparatus 1 according to an embodiment may further include a shower head 18. The shower head 18 may be arranged in the first space 101. The shower head 18 may be arranged under the ion blocker 13. The shower head 18 may be arranged with a certain interval from the ion blocker 13.

The shower head 18 may uniformly spray radicals and the like, which have passed through the ion blocker 13, to an upper portion of the first space 101. The shower head 18 may be arranged to face the substrate support 12. The shower head 18 may be formed of a conductive material and may have a plate shape, such as a circular plate. A constant voltage may be connected to the shower head 18, but the disclosure is not limited thereto. The shower head 18 may include a plurality of spray holes formed in an up-and-down direction. Radicals and the like may be sprayed to the first space 101 through the spray holes.

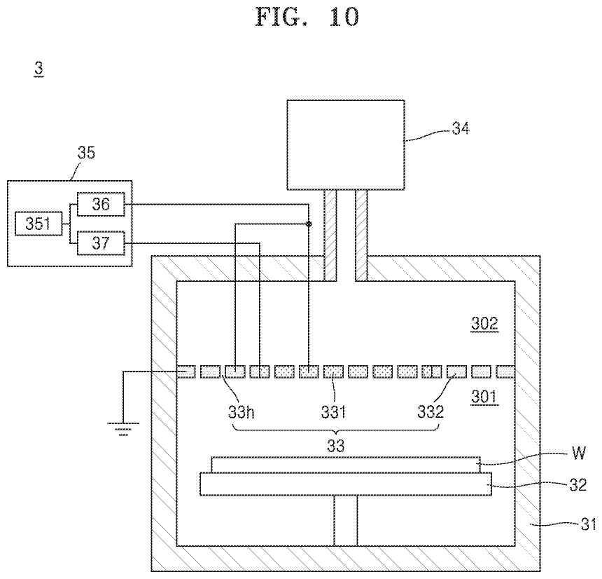

FIG. 10 is a diagram illustrating a substrate processing apparatus according to an embodiment. FIG. 10 shows a chamber 31 in a cross-sectional view.

Referring to FIG. 10, a substrate processing apparatus 3 according to an embodiment may include a chamber 31, a substrate support 32, an ion blocker 33, a plasma source 34, and a temperature controller 35.

Features of the chamber 31, the substrate support 32, the ion blocker 33, and the temperature controller 35 may be the same as those of the substrate processing apparatus 1 and repeated descriptions may be omitted.

The plasma source 34 may include a separate plasma chamber connected to the chamber 31. Unlike the substrate processing apparatus 1, plasma is not generated in the chamber 31, and plasma may be generated in the plasma chamber and supplied to a second space 302 of the chamber 31.

The plasma source 34 may be configured by an RPS. The plasma source 34 may convert a process gas and the like into plasma and supply the plasma to the second space 302 through a gas supply pipe or the like. The plasma source 34 may generate ions, radicals, and the like in the plasma chamber by using the process gas.

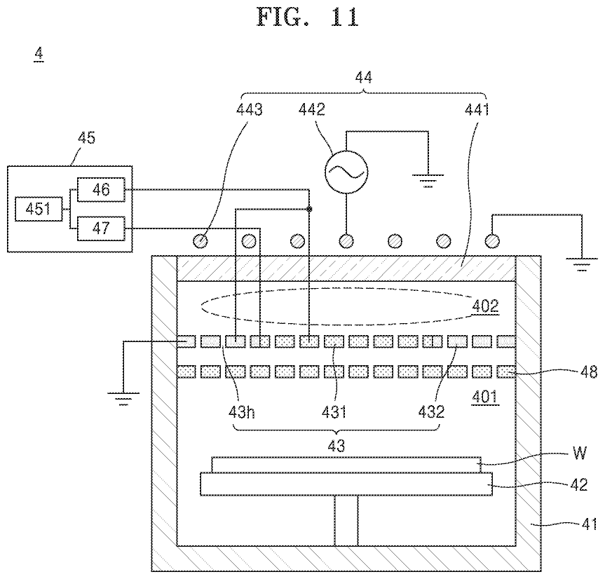

FIG. 11 is a diagram illustrating a substrate processing apparatus according to an embodiment. FIG. 11 shows a chamber 41 in a cross-sectional view.

Referring to FIG. 11, a substrate processing apparatus 4 according to an embodiment may include a chamber 41, a substrate support 42, an ion blocker 43, a plasma source 44, a temperature controller 45, and a shower head 48.

Features of the chamber 41, the substrate support 42, the ion blocker 43, the temperature controller 45, and the shower head 48 may be the same as those of the substrate processing apparatus 1 described above, and repeated descriptions may be omitted.

The plasma source 44 may include a dielectric layer 441, a radio frequency (RF) power supply 442, and coils 443. An upper portion of the chamber 41 may include the dielectric layer 441. The RF power supply 442 and the coils 443 may be arranged over the chamber 41. The RF power supply 442 and the coils 443 may each be grounded.

The coils 443 may be electrically driven by the RF power supply 442. When the RF power supply 442 applies power to the coils 443, a magnetic field may be formed. As a result, plasma may be generated in the second space 402 by using an induced electromagnetic field formed by the coils 443.

Each of the embodiments provided in the above description is not excluded from being associated with one or more features of another example or another embodiment also provided herein or not provided herein but consistent with the disclosure.

While the disclosure has been particularly shown and described with reference to embodiments thereof, it will be understood that various changes in form and details may be made therein without departing from the spirit and scope of the following claims.

What is claimed is:

1. A substrate processing apparatus, comprising:
a chamber comprising a first space and a second space;
a substrate support in the first space and configured to support a substrate;
a plasma source configured to generate plasma in the second space;
an ion blocker between the second space and the first space, the ion blocker comprising through-holes configured to:
pass therethrough radicals of the plasma from the second space to the first space; and
provide the radicals to the substrate; and
a temperature controller comprising:
a plurality of heaters connected to the ion blocker,
one or more chillers, and
a controller configured to control output of the plurality of heaters and output of the one or more chillers,
wherein the ion blocker further comprises:
a plurality of regions, each of the plurality of regions comprising a heating line, and
one or more boundary regions each comprising a cooling flow path between at least two of the plurality of regions and respectively connected to the one or more chillers,
wherein a temperature of each of the plurality of regions is independently controlled, and
wherein the heating lines of the plurality of regions are respectively connected to the plurality of heaters.

2. The substrate processing apparatus of claim 1, wherein the plurality of regions are electrically connected to each other.

3. The substrate processing apparatus of claim 2, wherein the plurality of regions are electrically grounded.

4. The substrate processing apparatus of claim 1, wherein each of the through-holes has a diameter that is equal to or smaller than twice of a thickness of a plasma sheath.

5. The substrate processing apparatus of claim 4, wherein the diameter of each of the through-holes is equal to or smaller than about 1 mm.

6. The substrate processing apparatus of claim 1, wherein a first region of the plurality of regions controlled to have a first temperature,
wherein a second region of the plurality of regions that is adjacent to the first region is controlled to have a second temperature that is different from the first temperature, and
where a boundary region of the one or more boundary regions that is between the first region of the plurality of regions and the second region of the plurality of regions is controlled to have a third temperature that corresponds to a temperature that is the lowest of the first temperature and the second temperature.

7. The substrate processing apparatus of claim 1, wherein the temperature controller further comprises a plurality of temperature sensors respectively configured to detect temperatures of the plurality of regions.

8. The substrate processing apparatus of claim 7, wherein the plurality of temperature sensors are configured to measure respective temperatures of the plurality of regions, and
wherein the temperature controller is configured to adjust the output of the plurality of heaters and the output of the one or more chillers based on the temperatures of the plurality of regions respectively measured by the plurality of temperature sensors.

9. The substrate processing apparatus of claim 1, wherein the ion blocker comprises a metal material.

10. The substrate processing apparatus of claim 1, further comprising an etch-resistant material layer extending along inner circumferential surfaces of the through-holes of the ion blocker.

11. The substrate processing apparatus of claim 1, wherein the through-holes have a same diameter, and
wherein the through-holes are uniformly arranged at a same interval between each other.

12. A substrate processing apparatus, comprising:
a chamber comprising a first space and a second space;
a plasma source configured to generate plasma in the second space;
a substrate support in the first space and configured to support a substrate; and
an ion blocker between the second space and the first space, the ion blocker comprising through-holes configured to:
pass therethrough radicals of the plasma from the second space to the first space; and
provide the radicals to the substrate,
wherein the ion blocker further comprises:
a first region comprising a first heating line connected to a first heater;
a second region comprising a second heating line connected to a second heater; and
a first boundary region between the first region and the second region, the first boundary region comprising a first cooling flow path connected to a first chiller, and
wherein a first temperature of the first region is controlled independently of a second temperature of the second region.

13. The substrate processing apparatus of claim 12, wherein the first heating line, the second heating line, and the first cooling flow path form a concentric circle.

14. The substrate processing apparatus of claim 12, wherein the ion blocker further comprises:
a third region outside the second region and comprising a third heating line connected to a third heater; and
a second boundary region between the second region and the third region, the second boundary region comprising a second cooling flow path connected to a second chiller.

15. The substrate processing apparatus of claim 14, wherein the first region, the second region and the third region are electrically connected to each other.

16. The substrate processing apparatus of claim 12, wherein the first boundary region is controlled to a third temperature that is equal to or smaller than the lowest temperature of the first temperature and the second temperature.

17. The substrate processing apparatus of claim 12, wherein each of the through-holes has a diameter that is equal to or smaller than twice of a thickness of a plasma sheath.

18. A substrate processing method comprising:
loading a substrate into a chamber;
generating plasma in the chamber;
controlling a temperature of an ion blocker in the chamber; and
processing the substrate using radicals of the plasma, the radicals having passed through the ion blocker,
wherein the ion blocker comprises:
a plurality of regions each comprising a heating line connected to a heater, and
one or more boundary regions between at least two of the plurality of regions, each of the one or more boundary regions comprising a cooling flow path connected to a chiller, and
wherein the controlling of the temperature of the ion blocker comprises independently controlling temperatures of each of the plurality of regions and temperatures of the one or more boundary regions.

19. The substrate processing method of claim 18, wherein the controlling of the temperature of the ion blocker comprises:
controlling a first region of the plurality of regions to have a first temperature, and
controlling a second region of the plurality of regions that is adjacent to the first region of the plurality of regions to have a second temperature that is different from the first temperature, and
wherein a boundary region of the one or more boundary regions that is between the first region of the plurality of regions and the second region of the plurality of regions is controlled to have a third temperature that corresponds to a temperature that is the lowest of the first temperature and the second temperature.

20. The substrate processing method of claim 18, wherein the generating of the plasma in the chamber comprises generating the plasma by at least one of a remote plasma source (RPS) method, a conductively coupled plasma (CCP) method, an inductively coupled plasma (ICP) method, and a microwave method.
